(19) United States
(12) Patent Application Publication
(10) Pub. No.: US 2014/0151780 A1
(43) Pub. Date: Jun. 5, 2014

(54) NONVOLATILE MEMORY DEVICE AND METHOD OF FABRICATING THE SAME

(71) Applicant: SK HYNIX INC., Gyeonggi-do (KR)

(72) Inventors: Sung-Kun PARK, Gyeonggi-do (KR); Young-Jun KWON, Gyeonggi-do (KR)

(73) Assignee: SK HYNIX INC., Gyeonggi-do (KR)

(21) Appl. No.: 13/830,983

(22) Filed: Mar. 14, 2013

(30) Foreign Application Priority Data
Nov. 30, 2012 (KR) 10-2012-0137637

(51) Int. Cl. H01L 29/788

(52) U.S. Cl. CPC H01L 29/788
USPC 257/316

(57) ABSTRACT

A nonvolatile memory device includes a floating gate formed over a substrate, a select gate formed adjacent to the floating gate with a gap defined therebetween, spacers formed on sidewalls of the floating gate and the select gate and filling the gap, a first junction region formed in the substrate adjacent to the floating gate, and a second junction region formed in the substrate adjacent to the select gate.

### CROSS-REFERENCE TO RELATED APPLICATIONS

The present application claims priority of Korean Patent Application No. 10-2012-0137637, filed on Nov. 30, 2012, the entire disclosure of which is incorporated herein by reference in its entirety.

### BACKGROUND

1. Field

Exemplary embodiments of the present invention relate to a semiconductor device fabrication technology, and more particularly, to a nonvolatile memory device and a method of fabricating the same.

2. Description of the Related Art

A life environment is being changed such that anyone may conveniently use desired information anytime and anywhere, thanks to recently developed digital media devices. As a conversion is made from analog to digital, a variety of rapidly spreading digital type devices have required storage media that may conveniently store captured images, recorded music and various data. In order to meet this requirement, there is a growing interest in the field of a system-on-chip (SoC) according to a tendency for a high degree of integration of non-memory semiconductors, and semiconductor manufacturers compete to invest in the field an SoC in an effort to strengthen an SoC-based technology. An SoC means that system technologies are integrated in one semiconductor. If a system design technology is not secured, it may be difficult to develop non-memory semiconductors.

One example of SoCs where complicated technologies are integrated is an embedded memory. It may be mentioned that a memory highlighted among embedded memories is a flash EEPROM (electrically erasable programmable read-only memory). This is because the flash EEPROM is a highly integrated nonvolatile memory device that may store data even in a power-off state like a ROM and may electrically erase and program data. In the flash EEPROM, since power consumption is reduced and high speed programming may be possible, the flash EEPROM is mainly adopted in a product in which a memory may be frequently modified.

EEPROMs include a single gate EEPROM (or a single poly EEPROM) that has one gate (for example, a floating gate), a stack gate (ETOX) EEPROM in which two gates (for example, a floating gate and a control gate) are vertically stacked, a dual gate EEPROM that corresponds to the middle of the single gate EEPROM and the stack gate EEPROM, and a split gate EEPROM.

In the EEPROMs, while the stack gate EEPROM, the dual gate EEPROM and the split gate EEPROM are advantageous over the single gate EEPROM in terms of high integration, they have a disadvantage in that they may undergo complicated processes in order to be formed together with a logic device such as a CMOS (complementary MOS) transistor. That is to say, limitations exist in applying the stack gate EEPROM, the dual gate EEPROM and the split gate EEPROM to an embedded memory, in view of productivity and yield.

Conversely, since the single gate EEPROM has a simplified standard process, it may be easily applied to an embedded memory. In other words, in the single gate EEPROM, because a memory function may be added in conformity with a standard logic process or a standard CMOS process without an additional process or an additional cost investment, the single gate EEPROM may be easily mounted to an embedded memory product. However, the single gate EEPROM has a disadvantage in comparison with the stack gate EEPROM, the dual gate EEPROM and the split gate EEPROM in that the degree of integration is low.

Accordingly, research is keenly demanded in the art, for a nonvolatile memory device that may be fabricated in conformity with a logic process like the single gate EEPROM without a separate additional process and may realize the degree of integration similar to or superior to the stack gate EEPROM, the dual gate EEPROM and the split gate EEPROM.

### SUMMARY

Various exemplary embodiments of the present invention are directed to a nonvolatile memory device that conforms to a logic process and is fabricated without a separate additional process, and a method of fabricating the same.

Also, various embodiments of the present invention are directed to a nonvolatile memory device that improves the degree of integration, and a method of fabricating the same.

In an exemplary embodiment of the present invention, a method of fabricating a nonvolatile memory device may include forming a gate conductive layer over a substrate, selectively etching the gate conductive layer, thereby forming at least one floating gate and simultaneously forming a select gate that is adjacent to the at least one floating gate with a gap defined therebetween, forming spacers on sidewalls of the at least one floating gate and the select gate to fill the gap, and forming a first junction region in a portion of the substrate adjacent to the at least one floating gate and a second junction region in a portion of the substrate adjacent to the select gate. The at least one floating gate and the select gate may define a gap therebetween, and the spacers fill the gap. The method further may comprise forming a first junction region in a portion of the substrate adjacent to the at least one floating gate; forming a second junction region in a portion of the substrate adjacent to the select gate; and forming a third junction region in a portion of the substrate under the gap. The select gate may be formed to have a sidewall that faces a sidewall of the at least one floating gate. The gate conductive layer may comprise a polysilicon layer and the spacers comprise a dielectric layer. The at least one floating gate may be coupled to the select gate in response to a voltage applied to the select gate. A coupling ratio between the at least one floating gate and the select gate may increase as a width of the gap decreases.

In another exemplary embodiment of the present invention, a method of fabricating a nonvolatile memory device may include forming a gate conductive layer over a substrate that has a logic region and a memory region, selectively etching the gate conductive layer, thereby forming gates in the logic region and simultaneously forming a floating gate and a select gate that is adjacent to the floating gate with a gap defined therebetween, in the memory region, forming spacers on sidewalls of the gates, the floating gate and the select gate to fill the gap, and forming impurity regions in portions of the substrate adjacent to the gates, in portions of the substrate adjacent to the floating gate and in portions of the substrate adjacent to the select gate. Before the forming of the spacers, the method further may comprise: forming a junction region in a portion of the substrate under the gap. The select gate may be formed to have a sidewall that faces a sidewall of the floating gate. The gate conductive layer comprises a polysilicon layer and the spacers comprise a dielectric layer.

In still another exemplary embodiment of the present invention, a nonvolatile memory device may include a floating gate formed over a substrate, a select gate formed adjacent to the floating gate with a gap defined therebetween, spacers formed on sidewalls of the floating gate and the select gate and filling the gap, a first junction region formed in a portion of the substrate adjacent to the floating gate, and a second junction region formed in a portion of the substrate adjacent to the select gate.

In still another exemplary embodiment of the present invention, a nonvolatile memory device may include a substrate having an active region that is defined by an isolation layer, a first junction region and a second junction region formed in end portions of the active region, a floating gate and a select gate formed over the active region between the first junction region and the second junction region, and adjacent to each other with a gap defined therebetween, and spacers formed on sidewalls of the floating gate and the select gate and filling the gap.

In still another exemplary embodiment of the present invention, a nonvolatile memory device may include a plurality of active regions, a plurality of gate lines crossing the plurality of active regions, junction regions formed in the active regions between the gate lines, and a first conductive line and a second conductive line respectively connected to one and the other junction regions when viewed on each of the plurality of gate lines, wherein each of the plurality of gate lines includes a plurality of floating gates, a select gate that is adjacent to the plurality of floating gates with gaps defined therebetween, and spacers that are formed on sidewalls of the floating gates and the select gate and fill the gaps. The nonvolatile memory device further may comprise a third junction region formed in a portion of the active region under the gap. The first junction region and the second junction region may comprise first impurity regions and second impurity regions that have larger impurity doping concentrations than those of the first impurity regions, and wherein the third junction region comprises an impurity region the same as the first impurity regions. The active region may comprise projections formed at the end portions of the active region, which correspond to the first and second junction regions. The select gate may have a sidewall that faces a sidewall of the floating gate. An upper surface of the floating gate and an upper surface of the select gate may be positioned on the same plane. The floating gate and the select gate comprise a polysilicon layer, and wherein the spacers comprise a dielectric layer. The floating gate may be coupled to the select gate in response to a voltage applied to the select gate. A coupling ratio between the select gate and the floating gate may increase as a width of the gap decreases.

### BRIEF DESCRIPTION OF THE DRAWINGS

FIG. 1A is a perspective view illustrating a unit cell of a nonvolatile memory device in accordance with an embodiment of the present invention.

FIG. 1B is a cross-sectional view taken along the line A-A′ of FIG. 1A.

FIG. 1C is a cross-sectional view taken along the line B-B′ of FIG. 1A.

FIG. 2A is a plan view illustrating variations of an active region in the unit cell of the nonvolatile memory device in accordance with the embodiment of the present invention.

FIG. 2B is a plan view illustrating variations of a floating gate and a select gate in the unit cell of the nonvolatile memory device in accordance with the embodiment of the present invention.

FIGS. 3A to 3D are cross-sectional views illustrating the processes of an exemplary method of fabricating the unit cell of the nonvolatile memory device in accordance with the embodiment of the present invention.

FIG. 4A is a cross-sectional view explaining a program operation of the unit cell of the nonvolatile memory device in accordance with the embodiment of the present invention.

FIG. 4B is a cross-sectional view explaining an erase operation of the unit cell of the nonvolatile memory device in accordance with the embodiment of the present invention.

FIGS. 4C and 4D are cross-sectional views explaining a read operation of the unit cell of the nonvolatile memory device in accordance with the embodiment of the present invention.

FIG. 5A is a plan view illustrating a cell array of the nonvolatile memory device in accordance with the embodiment of the present invention.

FIG. 5B is a cross-sectional view taken along the line A-A′ of FIG. 5A.

FIG. 6A is a plan view illustrating a cell array of a nonvolatile memory device in accordance with another embodiment of the present invention.

FIG. 6B is a cross-sectional view taken along the line A-A′ of FIG. 6A.

FIG. 7 is a block diagram showing a memory system including the nonvolatile memory device in accordance with the embodiments of the present invention.

FIG. 8 is a block diagram showing a memory card including the nonvolatile memory device in accordance with the embodiments of the present invention.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

Embodiments of the present invention that will be described below provide a nonvolatile memory device that is easily applicable to an embedded memory, and a method of fabricating the same. In detail, embodiments of the present invention provide a nonvolatile memory device that may be fabricated, without a separate additional process, in conformity with a logic process like a single gate EEPROM among flash EEPROMs and may have the degree of integration improved over the single gate EEPROM, and a method of fabricating the same.

For reference, because, in a single gate EEPROM that is generally known in the art, an impurity region such as a well that is formed in a substrate is used to couple a floating gate, a fabrication process conforms to a logic process and thus a separate additional process may not be needed. However, in the single gate EEPROM, limitations exist in increasing the degree of integration. In all of a stack gate EEPROM in which a floating gate and a control gate are vertically stacked, for example, a dual gate EEPROM in which a control gate and a floating gate are disposed side by side and a split gate EEPROM in which a control gate covers one side of a floating gate so that the control gate couples the floating gate, the degree of integration may be increased. However, since the floating gate and the control gate may not be simultaneously formed, a separate additional process other than a logic process may be needed.

In consideration of these facts, the embodiments of the present invention that will be described below provide a nonvolatile memory device that has a floating gate and a select gate with an over-erase preventing function, as a control gate for coupling the floating gate, thereby increasing the degree of integration and allowing the floating gate and the control gate to be simultaneously formed on the basis of a logic process, and a method of fabricating the same.

Meanwhile, in the following descriptions, a first conductivity type and a second conductivity type mean complementary conductivity types. Namely, if the first conductivity type is a P type, the second conductivity type is an N type, and, if the first conductivity type is an N type, the second conductivity type is a P type. This means that a nonvolatile memory device in accordance with embodiments of the present invention may be an N-channel type or a P-channel type. Hereinafter, for the sake of convenience in explanation, the first conductivity type will be described as a P type and the second conductivity type will be described as an N type. That is to say, descriptions will be made below by exemplifying an N-channel type nonvolatile memory device.

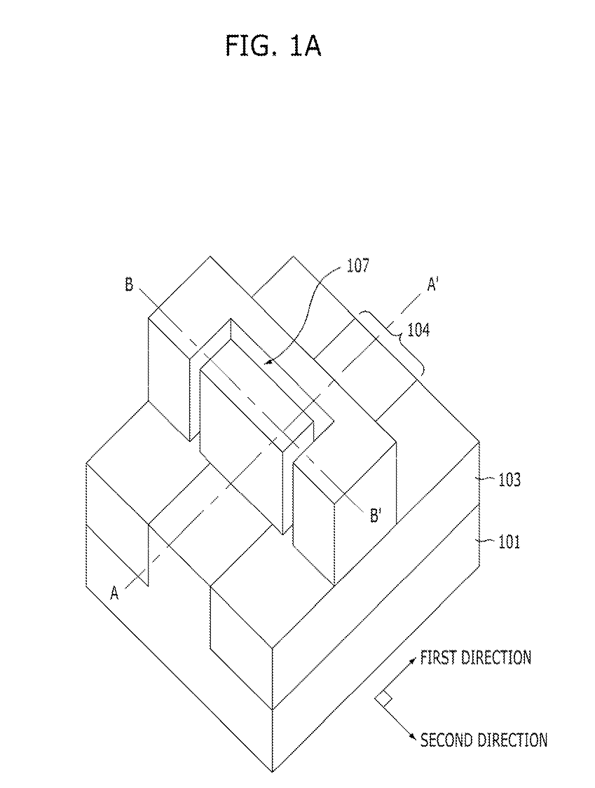

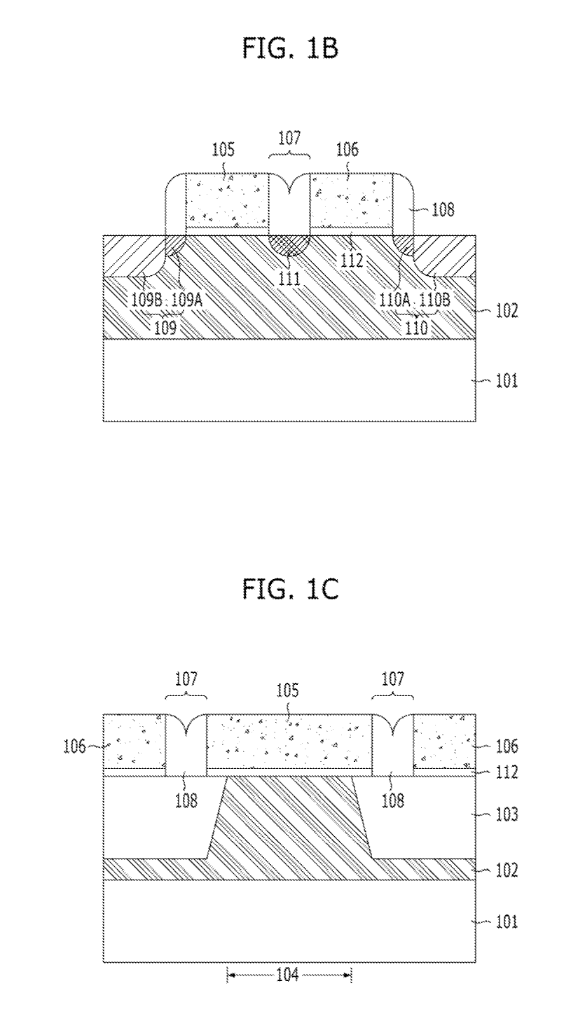

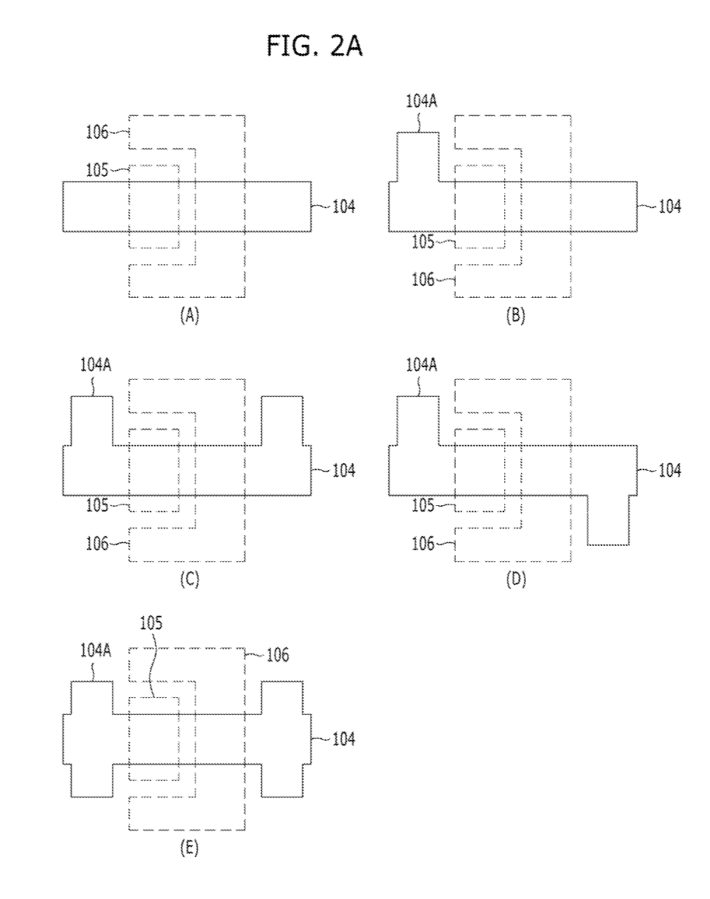

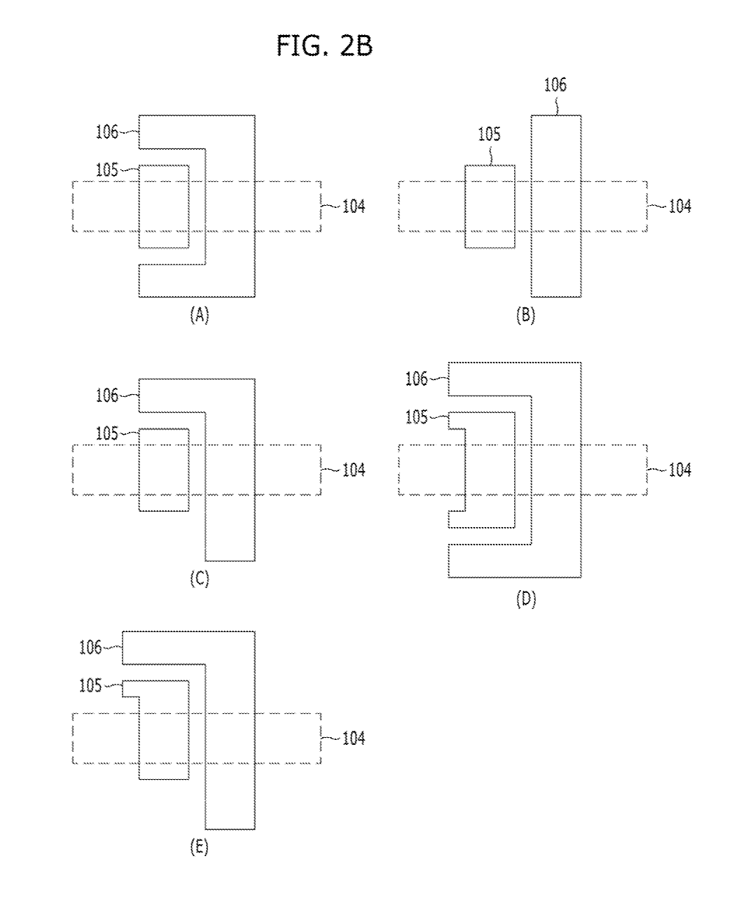

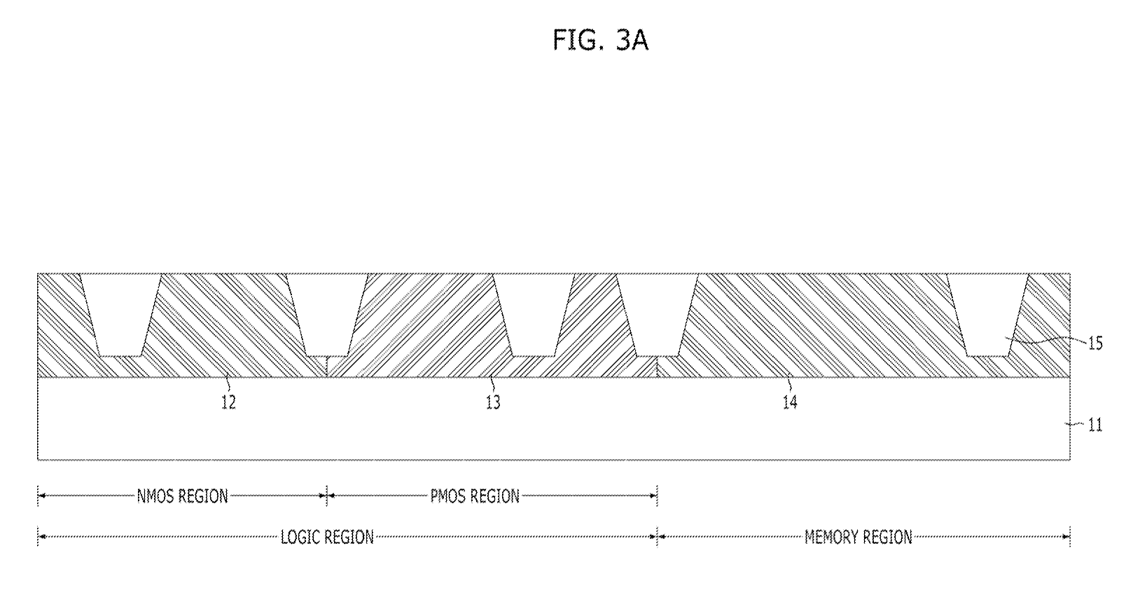

FIGS. 1A to 1C are views illustrating a unit cell of a nonvolatile memory device in accordance with a first embodiment of the present invention. In detail, FIG. 1A is a perspective view, and FIGS. 1B and 1C are cross-sectional views taken along the lines A-A′ and B-B′ of FIG. 1A. FIG. 2A is a plan view illustrating variations of an active region in the unit cell of the nonvolatile memory device in accordance with the embodiment of the present invention, and FIG. 2B is a plan view illustrating variations of a floating gate and a select gate in the unit cell of the nonvolatile memory device in accordance with the embodiment of the present invention.

Referring to FIGS. 1A to 1C, a first conductivity type well 102 is formed in a substrate 101. The substrate 101 may be a semiconductor substrate. The semiconductor substrate may be in a single crystalline state, and may include a silicon-containing substance. That is to say, the semiconductor substrate may include a single crystalline silicon-containing substance. For instance, the substrate 101 may be a bulk silicon substrate, or an SOI (silicon-on-insulator) substrate in which a supporting substrate, a buried dielectric layer and a single crystalline silicon layer are sequentially stacked. The first conductivity type well 102 is to provide a base on which a unit cell may operate. The first conductivity type well 102 may be formed by ion-implanting impurities of the first conductivity type into the substrate 101.

An isolation layer 103 is formed in the substrate 101 in such a way as to define an active region 104. The isolation layer 103 may be formed through an STI (shallow trench isolation) process, and may include a dielectric layer. When measured from the surface of the substrate 101, the depth of the isolation layer 103 may be smaller than the depth of the well 102. Meanwhile, as the case may be, the depth of the isolation layer 103 may be larger than the depth of the well 102.

The active region 104 that is defined by the isolation layer 103 may be a bar type or a line type, which has the major axis extending in a first direction and the minor axis extending in a second direction crossing (or perpendicular to) the first direction (see (A) of FIG. 2A). Referring to FIG. 2A, the active region 104 may include one or more projections 104A that project in the second direction for contact of junction regions (that is, a source region and a drain region) formed at both end portions of the active region 104 and conductive lines to be connected to the junction regions. The one or more projections 104A may have a shape that is formed at one end portion on one side or the other side of the active region 104 (see (B) of FIG. 2A), shapes that are formed at both end portions on one side or the other side of the active region 104 to extend in the same direction (see (C) of FIG. 2A), shapes that are formed at both end portions each on each of both sides of the active region 104 to extend in different directions (or to be disposed zigzag) (see (D) of FIG. 2A), and shapes that are formed at both end portions on both sides of the active region 104 (see (E) of FIG. 2A). The shapes of the projections 104A may be changed according to a disposition of the conductive lines that are connected with the junction regions.

On the substrate 101, there are formed a floating gate (FG) 105, and a select gate (SG) 106 that is adjacent to the floating gate 105 with a gap 107 defined therebetween. That is to say, the select gate 106 may have a shape that has one sidewall facing at least one sidewall of the floating gate 105. While it is exemplified that the floating gate 105 and the select gate 106 are planar gates, the floating gate 105 and the select gate 106 may be formed to have three-dimensional gate structures, for example, such as fin gates.

The floating gate 105 performs a function of storing logic information. The select gate 106 performs the function of a control gate that couples the floating gate 105 in a program operation, an erase operation and a read operation, and performs the function of preventing over-erase in the erase operation.

In the first direction, the floating gate 105 may have a structure that is positioned at the middle portion of the active region 104 and overlaps the active region 104. In the second direction, the floating gate 105 may have a structure that covers the active region 104 and of which both ends overlap the isolation layer 103. In other words, the width of the floating gate 105 in the second direction may be the same as or larger than the width of the active region 104 in the second direction. Referring to FIG. 2B, the floating gate 105 may have a bar-like shape (see (A) of FIG. 2B), a shape both ends of which slightly project (see (D) of FIG. 2B), or a shape one end of which slightly projects (see (E) of FIG. 2B). For reference, the floating gate 105 having a shape both ends or one end of which slightly projects is a structure to increase the area of a sidewall that faces the select gate 106 and thereby increase the coupling ratio between the floating gate 105 and the select gate 106.

In the first direction, the select gate 106 may be positioned at the middle portion of the active region 104 and may be disposed side by side with the floating gate 105. In the second direction, the select gate 106 may have a structure both ends of which overlap the isolation layer 103, and may be disposed parallel to the floating gate 105 (see (A) and (E) of FIG. 2B). Namely, in the second direction, a structure may be formed in which both sidewalls of the floating gate 105 and both ends of the select gate 106 may face each other. This is to increase the area of sidewalls of the floating gate 105 and the select gate 106, which face each other and thereby increase the coupling ratio between the floating gate 105 and the select gate 106.

Meanwhile, as the case may be, if the coupling ratio between the floating gate 105 and the select gate 106 may be sufficiently secured, the select gate 106 may have a shape (see (C) and (E) of FIG. 2B) that has a sidewall facing one sidewall or the other sidewall of the floating gate 105 or a bar (or a line) shape (see (B) of FIG. 2B), in the second direction. In this case, advantages are provided in that the degree of integration of the nonvolatile memory device in accordance with the embodiment of the present invention may be increased and difficulty of a fabrication process may be lessened.

The select gate 106 is adjacent to the floating gate 105 with the gap 107 defined therebetween, and the width of the gap 107 is constant in the first direction and the second direction. In detail, the gap 107 is defined between the sidewalls of the floating gate 105 and the select gate 106 facing each other, and has a constant width between the floating gate 105 and the select gate 106. The gap 107 is to provide a space in which a dielectric layer (for example, an IPD) for insulating the floating gate 105 and the select gate 106 from each other is to be formed. Accordingly, the width of the gap 107 may be controlled in consideration of the design margin, forming processes and operation characteristics of a unit cell. In detail, the width of the gap 107 may be controlled in consideration of the design rule of the unit cell, the coupling ratio between the select gate 106 and the floating gate 105, and so on. As the width of the gap 107 decreases, the coupling ratio between the floating gate 105 and the select gate 106 may be increased. For instance, the gap 107 may have a width in the range of 30 nm to 90 nm.

A gate dielectric layer 112 is formed between the floating gate 105 and the substrate 101 and between the select gate 106 and the substrate 101. The gate dielectric layer 112 may be any one single layer selected from the group consisting of an oxide layer, a nitride layer and an oxynitride layer, or a stack layer thereof.

Spacers 108 are formed on the sidewalls of the floating gate 105 and the select gate 106 facing each other in the first direction and the second direction, and the gap 107 is filled by the spacers 108. The spacers 108 that fill the gap 107 serve as a dielectric layer (for example, an IPD) that insulates the floating gate 105 and the select gate 106 from each other. Accordingly, the spacers 108 include a dielectric layer, and the dielectric layer may be any one single layer selected from the group consisting of an oxide layer, a nitride layer and an oxynitride layer, or a stack layer thereof. The dielectric layer used as the spacers 108 may be selected among various known substances in consideration of a coupling ratio between the select gate 106 and the floating gate 105.

As will be discussed later in a method of fabricating the unit cell of the nonvolatile memory device, the floating gate 105 and the select gate 106 are simultaneously formed by etching the same gate conductive layer. Accordingly, the floating gate 105 and the select gate 106 are positioned on the same plane. In other words, the upper surface of the floating gate 105 and the upper surface of the select gate 106 may be positioned on the same plane. The select gate 106 may have a shape that covers the sidewalls and the upper surface of the floating gate 105 to increase the coupling ratio between the floating gate 105 and the select gate 106. However, in this case, the shape may be realized, for example, only when the floating gate 105 and the select gate 106 are formed through a separate process other than a logic process. Namely, the fact that the upper surface of the floating gate 105 and the upper surface of the select gate 106 are positioned on the same plane means that the floating gate 105 and the select gate 106 are structures that are simultaneously formed through the logic process.

The floating gate 105 and the select gate 106 may include the same substance. The floating gate 105 and the select gate 106 may include a silicon-containing substance. For instance, the floating gate 105 and the select gate 106 may include a polysilicon layer. The polysilicon layer may be a doped polysilicon layer doped with impurities of the second conductivity type or an undoped polysilicon layer not doped with impurities.

A first junction region 109 is formed in the active region 104 adjacent to the floating gate 105, a second junction region 110 is formed in the active region 104 adjacent to the select gate 106, and a third junction region 111 is formed in the active region 104 between the floating gate 105 and the select gate 106. That is to say, the first junction region 109 and the second junction region 110 are respectively formed in both end portions of the active region 104 in the first direction, and the third junction region 111 is formed in the middle portion of the active region 104 between the first junction region 109 and the second junction region 110. The floating gate 105 and the select gate 106 are respectively positioned on the active region 104 between the first junction region 109 and the third junction region 111 and on the active region 104 between the third junction region 111 and the second junction region 110. The spacers 108 that fill the gap 107 between the floating gate 105 and the select gate 106 are positioned on the third junction region 111.

The first junction region 109, the second junction region 110 and the third junction region 111 may be impurity regions that are formed by ion-implanting impurities of the second conductivity type into the substrate 101. The first junction region 109 and the second junction region 110 serve as a source region and a drain region. The first junction region 109 and the second junction region 110 may have LDD structures. In detail, the first junction region 109 includes a first impurity region 109A and a second impurity region 109B both having the second conductivity type, and the second junction region 110 includes a first impurity region 110A and a second impurity region 1106 both having the second conductivity type. The impurity doping concentration of the second impurity regions 109B and 1106 may be larger than the impurity doping concentration of the first impurity regions 109A and 110A. The third junction region 111 performs a function of electrically connecting channels induced in the active region 104 by the select gate 106 and the floating gate 105. The third junction region 111 may have the same conductivity type and the same impurity doping concentration as the first impurity regions 109A and 110A of the second conductivity type. Namely, the third junction region 111 may be simultaneously formed in a process for forming the first impurity regions 109A and 110A.

As the nonvolatile memory device having the above-described structure includes the floating gate 105 and the select gate 106 that are positioned on the same plane, the degree of integration and operation characteristics may be improved when compared to a single gate EEPROM.

Also, in the nonvolatile memory device in accordance with the embodiment of the present invention, because a coupling ratio increases as the width of the gap 107 between the floating gate 105 and the select gate 106 decreases, the degree of integration and operation characteristics may be further improved as the degree of integration of a nonvolatile memory device increases. That is to say, in the nonvolatile memory device in accordance with the embodiment of the present invention, as the technology of the logic process as a base process is improved and the degree of integration of a nonvolatile memory device increases, the degree of integration and operation characteristics may be further improved.

Moreover, in the nonvolatile memory device in accordance with the embodiment of the present invention, since the floating gate 105 and the select gate 106 are positioned on the same plane and the spacers 108 formed on the sidewalls of the floating gate 105 and the select gate 106 serve as a dielectric layer, it may be possible to fabricate a nonvolatile memory device in conformity with the logic process without a separate additional process.

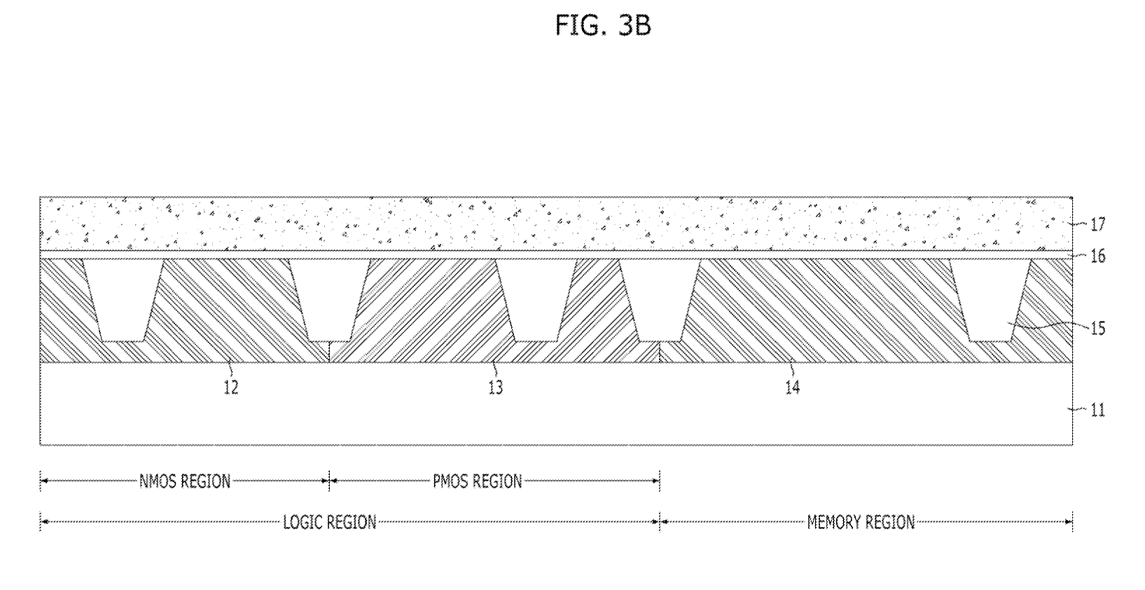

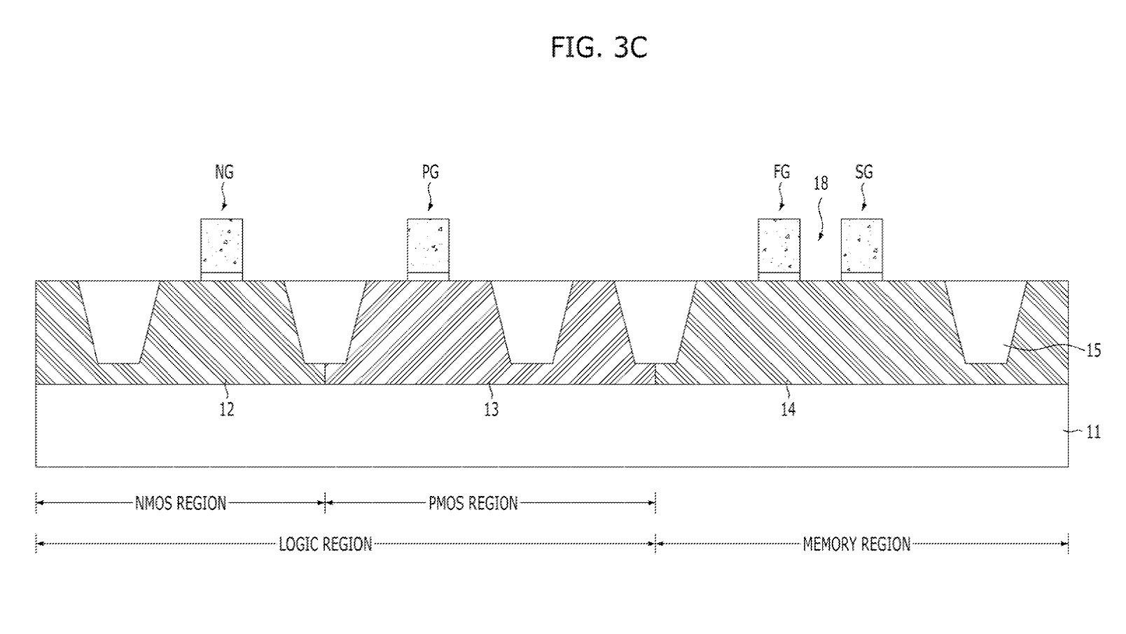

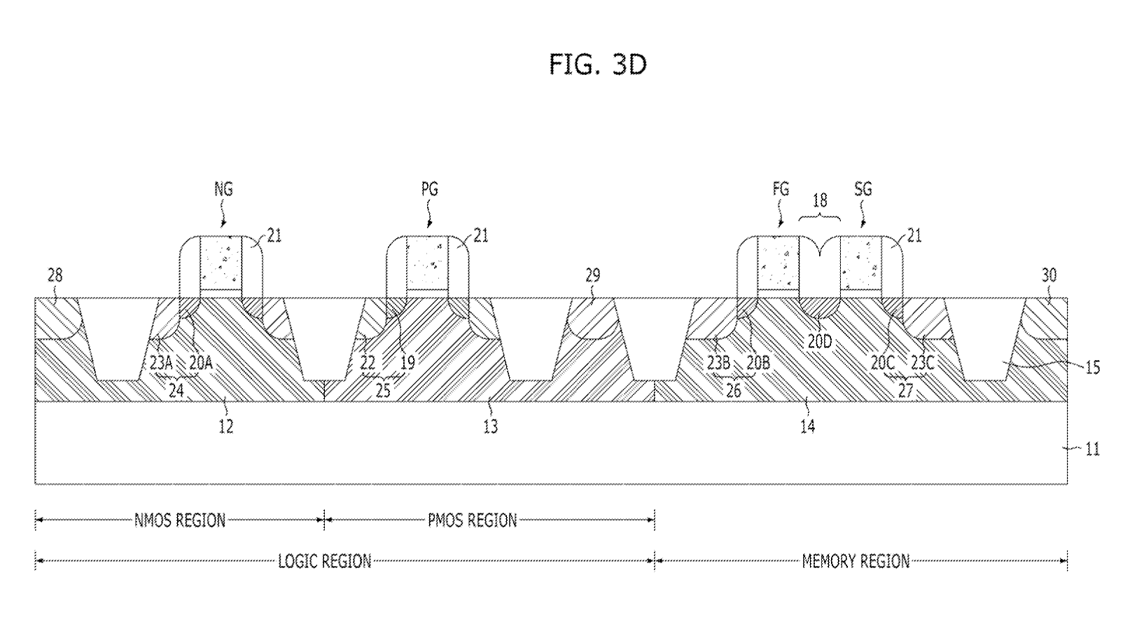

Hereinbelow, the fact that the nonvolatile memory device in accordance with the embodiment of the present invention may be formed in conformity with the logic process without a separate additional process will be explained in detail with reference to FIGS. 3A to 3D, through a method of fabricating the nonvolatile memory device having the above-described structure.

FIGS. 3A to 3D are cross-sectional views illustrating the processes of an exemplary method of fabricating the unit cell of the nonvolatile memory device in accordance with the embodiment of the present invention. In these drawings, the unit cell of the nonvolatile memory device is shown by being taken along the line A-A′ of FIG. 1A.

Referring to FIG. 3A, a substrate 11 having a logic region and a memory region is prepared. The logic region may include an NMOS region and a PMOS region. The substrate 11 may use a semiconductor substrate. The semiconductor substrate may be in a single crystalline state, and may include a silicon-containing substance. In other words, the semiconductor substrate may include a single crystalline silicon-containing substance. For instance, as the substrate 11, a bulk silicon substrate or an SOI (silicon-on-insulator) substrate may be used.

A first well 12, a second well 13 and a third well 14 are formed in the substrate 11 in such a way as to respectively correspond to the NMOS region, the PMOS region and the memory region. The first well 12 may be formed by ion-implanting impurities of the first conductivity type into the substrate 11, and the second well 13 may be formed by ion-implanting impurities of the second conductivity type into the substrate 11. The third well 14 corresponding to the memory region may be controlled in its conductivity type according to a channel type of a memory. For instance, in the case where the memory is an N-channel type, the third well 14 may be formed by ion-implanting impurities of the first conductivity type (that is, P type impurities) into the substrate 11. The first well 12, the second well 13 and the third well 14 may contact each other, and since their respective conductivity types are different from each other, junction isolations are formed between them.

An isolation layer 15 is formed in the substrate 11. The depth of the isolation layer 15 may be smaller than the depths of the first well 12, the second well 13 and the third well 14. The isolation layer 15 may be formed through an STI (shallow trench isolation) process. The STI process means a series of processes of forming the isolation layer 15 by defining trenches for isolation in the substrate 11 and filling a dielectric substance in the trenches.

Referring to FIG. 3B, a gate dielectric layer 16 is formed on the entire surface of the substrate 11. The gate dielectric layer 16 may be formed as any one single layer selected from the group consisting of an oxide layer, a nitride layer and an oxynitride layer, or a stack layer thereof.

A gate conductive layer 17 is formed on the gate dielectric layer 16. The gate conductive layer 17 may be formed of a silicon-containing substance, and a silicon layer may be used as the silicon-containing substance. For instance, the gate conductive layer 17 may be formed as a polysilicon layer.

Impurities are ion-implanted into portions of the gate conductive layer 17, which respectively correspond to the NMOS region, the PMOS region and the memory region. This is to provide characteristics (for example, work functions) of the gate conductive layer 17, which are demanded in the respective regions. For example, impurities of the first conductivity type may be ion-implanted into the gate conductive layer 17 corresponding to the PMOS region, and impurities of the second conductivity type may be ion-implanted into the gate conductive layer 17 corresponding to the NMOS region. Any impurities may not be ion-implanted into the gate conductive layer 17 corresponding to the memory region, or predetermined impurities may be ion-implanted into the gate conductive layer 17 corresponding to the memory region according to a channel type of the memory. For instance, impurities of the second conductivity type may be ion-implanted into the gate conductive layer 17 corresponding to the memory region.

Referring to FIG. 3C, after forming mask patterns (not shown) on the gate conductive layer 17 and sequentially etching the gate conductive layer 17 and the gate dielectric layer 16 using the mask patterns as an etch barrier, a plurality of gates NG, PG and FG, SG are formed. In detail, a first gate NG and a second gate PG are respectively formed in the NMOS region and the PMOS region Also, a floating gate FG and a select gate SG that is adjacent to the floating gate FG with a gap 18 defined therebetween are formed in the memory region. All of the first gate NG, the second gate PG, the floating gate FG and the select gate SG are simultaneously formed through one etching process.

Since the shapes and dispositions of the floating gate FG and the select gate SG in the memory region are described above in detail with reference to FIGS. 1A to 1C and FIG. 2B, detailed descriptions thereof will be omitted herein.

Referring to FIG. 3D, by ion-implanting impurities of the first conductivity type into the substrate 11 on both sides of the second gate PG, first impurity regions 19 are formed. By ion-implanting impurities of the second conductivity type into the substrate 11 on both sides of the first gate NG, second impurity regions 20A are formed. Also, by ion-implanting impurities of the second conductivity type into the substrate 11 on both sides of the floating gate FG and the select gate SG, second impurity regions 20B, 20C and 20D are formed.

Spacers 21 are formed on the sidewalls of the first gate NG, the second gate PG, the floating gate FG and the select gate SG. The spacers 21 are formed to fill the gap 18 between the floating gate FG and the select gate SG. The spacers 21 may be formed as a dielectric layer. The dielectric layer may be any one single layer selected from the group consisting of an oxide layer, a nitride layer and an oxynitride layer, or a stack layer thereof. The spacers 21 may be formed through a series of processes of depositing a dielectric layer on the surface of the structure including the first gate NG, the second gate PG, the floating gate FG and the select gate SG in such a way as to fill the gap 18 and then performing blanket etching, for example, etch-back.

By ion-implanting impurities of the first conductivity type into the substrate 11 on both sides of the second gate PG including the spacers 21, third impurity regions 22 are formed. Fourth impurity regions 23A are formed in the substrate 11 on both sides of the first gate NG including the spacers 21. Also, fourth impurity regions 23B and 23C are formed in the substrate 11 on the other side of the floating gate FG and one side of the select gate SG including the spacers 21. The third impurity regions 22 may be formed to have an impurity doping concentration larger than that of the first impurity regions 19. The fourth impurity regions 23A, 23B and 23C may be formed to have impurity doping concentrations larger than those of the second impurity regions 20A, 20B, 20C and 20D.

Through the above-described processes, a source/a drain 24 of the second conductivity type with an LDD structure that is constituted by the second impurity region 20A and the fourth impurity region 23A may be formed in the NMOS region. A source/a drain 25 of the first conductivity type with an LDD structure that is constituted by the first impurity region 19 and the third impurity region 22 may be formed in the PMOS region. A first junction region 26 and a second junction region 27 with LDD structures that are respectively constituted by the second impurity region 20B and the fourth impurity region 23B and by the second impurity region 20C and the fourth impurity region 23C may be formed in the memory region. The second impurity region 20D that is formed in the substrate 11 under the spacers 21 filling the gap 18 between the floating gate FG and the select gate SG serves as a third junction region.

The unexplained reference numeral 28 designates a pick-up region of the first well 12 that may be formed by ion-implanting impurities of the first conductivity type. The unexplained reference numeral 29 designates a pick-up region of the second well 13 that may be formed by ion-implanting impurities of the second conductivity type. The unexplained reference numeral 30 designates a pick-up region of the third well 14 that may be formed by ion-implanting impurities of the first conductivity type.

As can be readily seen from the above descriptions, in the method of fabricating the nonvolatile memory device in accordance with the embodiment of the present invention, it may be possible to fabricate a nonvolatile memory device that has the floating gate FG and the select gate SG, in conformity with the logic process without a separate additional process.

Furthermore, in the method of fabricating the nonvolatile memory device in accordance with the embodiment of the present invention, since the floating gate FG and the select gate SG are simultaneously formed and a dielectric layer between the floating gate FG and the select gate SG is formed through a process for forming the spacers 21, processes may be simplified in comparison with a conventional EEPROM and the number of process steps may be decreased, whereby productivity and yield may be increased.

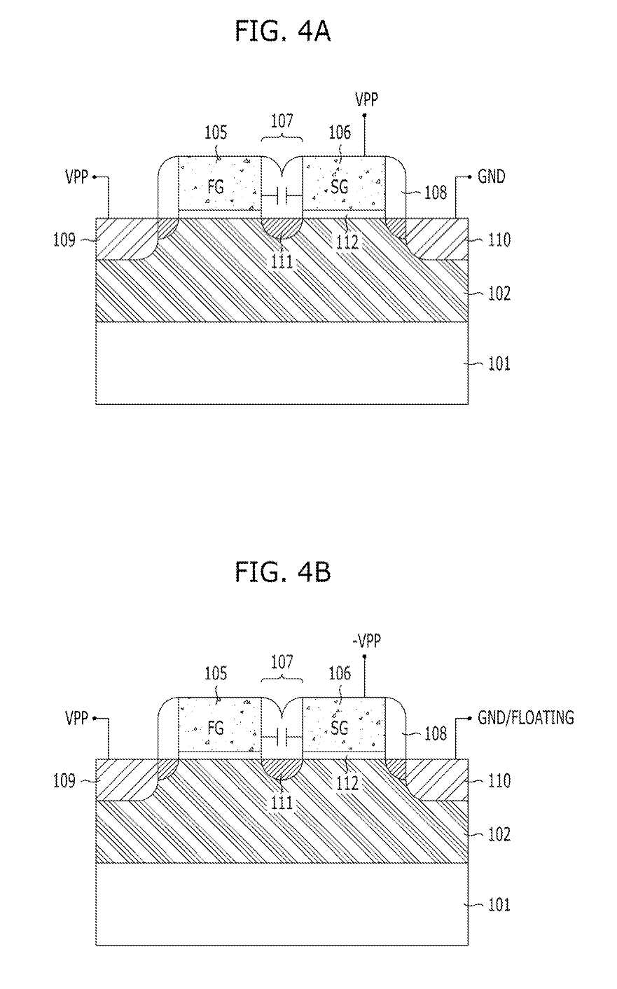

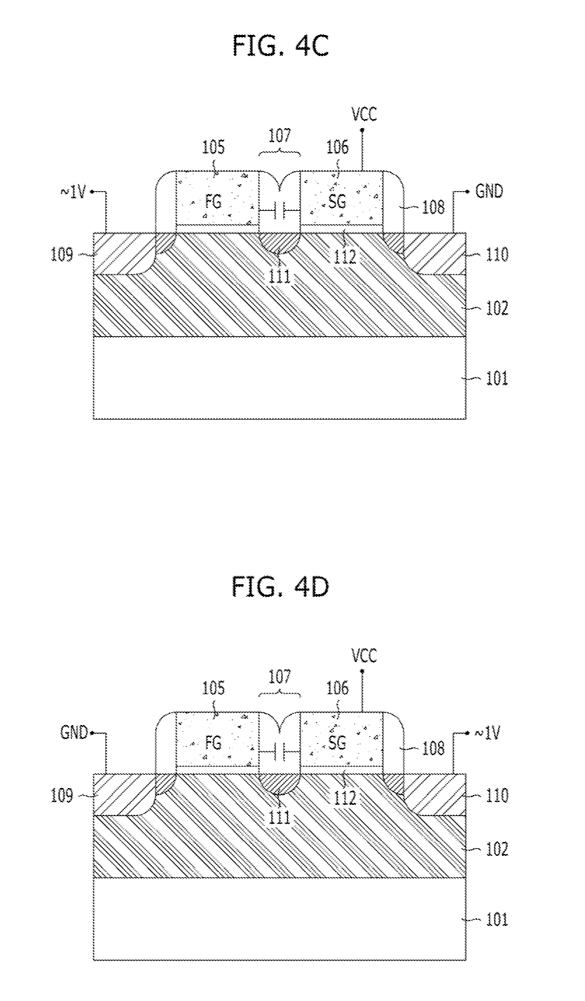

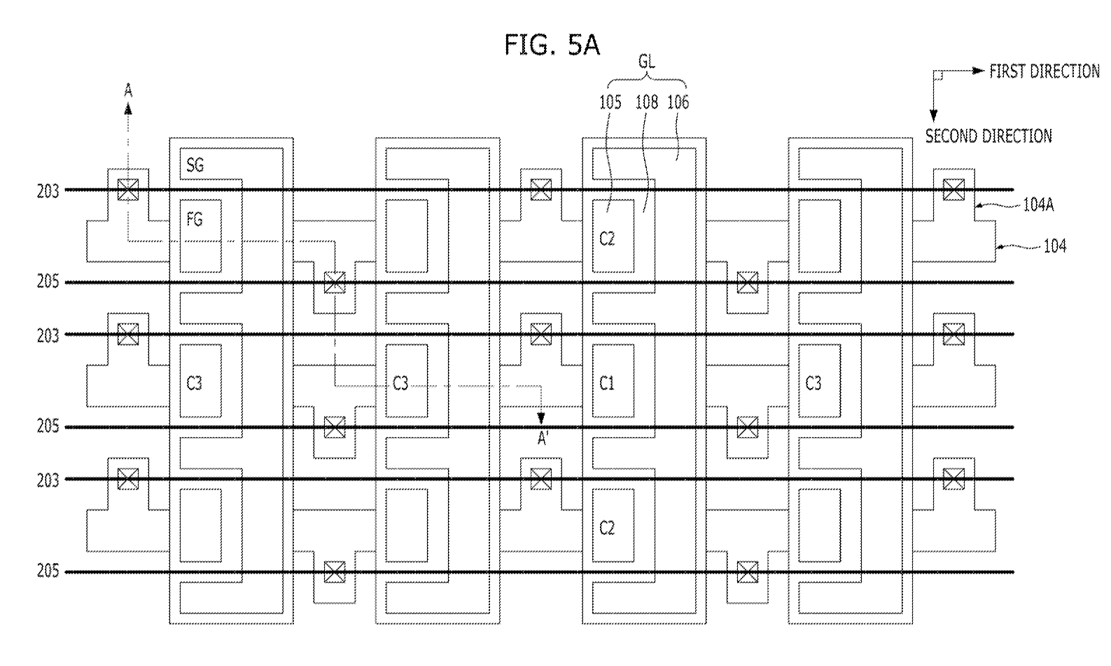

Hereinbelow, operation methods of the unit cell of the nonvolatile memory device in accordance with the embodiment of the present invention will be described with reference to Table 1 and FIGS. 4A to 4D. For the sake of convenience in explanation, the same reference numerals as those of FIGS. 1A to 1C will be used in FIGS. 4A to 4D.

FIGS. 4A to 4D are views explaining operations of the unit cell of the nonvolatile memory device in accordance with the embodiment of the present invention. In detail, FIG. 4A is a cross-sectional view explaining a program operation, FIG. 4B is a cross-sectional view explaining an erase operation, and FIGS. 4C and 4D are cross-sectional views explaining a read operation. Table 1 shows operating conditions of the unit cell of the nonvolatile memory device in accordance with the embodiment of the present invention.

Before describing operation methods of the unit cell of the nonvolatile memory device in accordance with the embodiment of the present invention, the N channel given in Table 1 means the case where the conductivity type of the well 102 is a P type and the conductivity types of the first junction region 109, the second junction region 110, and the third junction region 111 are N types, that is, the case where the conductivity type of a channel induced by the floating gate 105 and the select gate 106 is an N type or the channel is constituted by electrons. Further, the P channel given in Table 1 means the case where the conductivity type of the well 102 is an N type and the conductivity types of the first junction region 109, the second junction region 110, and the third junction region 111 are P types, that is, the case where the conductivity type of a channel induced by the floating gate 105 and the select gate 106 is a P type or the channel is constituted by holes.

TABLE 1

| | | | | First | Second | |
|---|---|---|---|---|---|---|
| | | | Select | junction | junction | Substrate |
| | Operation | Type | gate | region | region | (or well) |
| N | Program | HCI | VPP | VPP | GND | GND |
| channel | Erase | BTBT | −VPP | VPP | GND/ | GND |
| | | | | | Floating | |
| | Read | — | VCC | GND/~1 V | ~1 V/GND | GND |
| P | Program | BTBT | VPP | −VPP | GND | GND |
| channel | Erase | DAH | −VPP | −VPP | GND/ | GND |
| | | | | | Floating | |
| | Read | — | VCC | GND/~1 V | V/GND | GND |

A program operation of the unit cell of the nonvolatile memory device in accordance with the embodiment of the present invention will be described below with reference to Table 1 and FIG. 4A.

A program operation in the unit cell with the N channel may use HCI (hot carrier injection). In detail, as a first operation voltage, a program voltage and a ground voltage GND are respectively applied to the select gate 106, the first junction region 109 and the second junction region 110, charges (for example, electrons) are injected into the floating gate 105, and thus, program may be performed in such a way as to increase the threshold voltage of the floating gate 105.

The first operation voltage and the program voltage may be positive voltages. For instance, the first operation voltage and the program voltage may be a pumping voltage VPP. For reference, the pumping voltage VPP means a voltage that is generated by boosting a power supply voltage VCC supplied from an outside.

As the pumping voltage VPP is applied to the select gate 106, a channel is formed in the substrate 101 under the select gate 106, and a channel is formed in the substrate 101 under the floating gate 105 that is coupled by the select gate 106. The two channels are connected with each other by the third junction region 111, and the channel under the floating gate 105 is pinched off by the pumping voltage VPP applied to the first junction region 109. Hot electrons generated in a pinch-off region are injected into the floating gate 105, and the threshold voltage of the floating gate 105 is increased, by which the unit cell may be programmed. This program method provides an advantage in that program may be easily performed even when the coupling ratio between the floating gate 105 and the select gate 106 is smaller than that in FN (Fowler-Nordheim tunneling).

A program operation in the unit cell with the P channel may use BTBT (band to band tunneling). In detail, the unit cell may be programmed by applying a pumping voltage VPP to the select gate 106, applying a negative pumping voltage −VPP to the first junction region 109 and applying a ground voltage GND to the second junction region 110.

An erase operation of the unit cell of the nonvolatile memory device in accordance with the embodiment of the present invention will be described below with reference to Table 1 and FIG. 4B.

An erase operation in the unit cell with the N channel may use BTBT (band to band tunneling). In detail, by respectively applying a second operation voltage and an erase voltage to the select gate 106 and the first junction region 109 and applying a ground voltage GND to the second junction region 110 or floating the second junction region 110, charges (for example, holes) are injected into the floating gate 105, and thus, erase may be performed in such a way as to decrease the threshold voltage of the floating gate 105. The second operation voltage may be a negative voltage, and the erase voltage may be a positive voltage. For reference, the second operation voltage may be a negative pumping voltage −VPP, and the erase voltage may be a pumping voltage VPP.

As the negative pumping voltage −VPP is applied to the select gate 106, the floating gate 105 is coupled by a negative voltage. As BTBT occurs between the first junction region 109 applied with the pumping voltage VPP and the floating gate 105 coupled by the negative voltage, holes having large energy are injected into the floating gate 105 by the negative voltage of the floating gate 105, and the threshold voltage of the floating gate 105 is decreased, by which the unit cell may be programmed. In particular, in the case of an already programmed unit cell, since the floating gate 105 itself has negative potential, a large amount of holes are injected into the floating gate 105, by which an erase operation characteristic may be improved.

Meanwhile, an erase operation in the unit cell with the P channel may use DAH (drain avalanche hot carrier). In detail, the unit cell may be programmed by applying a negative pumping voltage −VPP to the select gate 106, applying a negative pumping voltage −VPP to the first junction region 109 and applying a ground voltage GND to the second junction region 110 or floating the second junction region 110.

A read operation of the unit cell of the nonvolatile memory device in accordance with the embodiment of the present invention will be described below with reference to Table 1 and FIGS. 4C and 4D.

A read operation may be classified into forward read and reverse read. The forward read means that a read operation is performed through charge migration in the same direction as a migrating direction of charges in the program operation (see FIG. 4C), and reverse read means that a read operation is performed through charge migration in a direction opposite to a migrating direction of charges in the program operation (see FIG. 4D).

Because the forward read may realize a cell array with a simple structure when compared to the reverse read, it provides advantages in terms of the degree of integration and the difficulty of processing. On the contrary, the reverse read has an advantage in that immunity to read disturbance is superior to the forward read.

In the forward read, a third operation voltage, a read voltage and a ground voltage GND may be respectively applied to the select gate 106, the first junction region 109 and the second junction region 110 (see FIG. 4C). In the reverse read, a third operation voltage, a ground voltage GND and a read voltage may be respectively applied to the select gate 106, the first junction region 109 and the second junction region 110 (see FIG. 4D). The third operation voltage and the read voltage may be positive voltages. The read voltage may be smaller than the third operation voltage, and the third operation voltage may be smaller than the first operation voltage. For instance, the third operation voltage may be a power supply voltage VCC, and the read voltage may be 1V.

Hereinbelow, a cell array that is constituted on the basis of the above-described unit cell of the nonvolatile memory device and the operation methods thereof will be described.

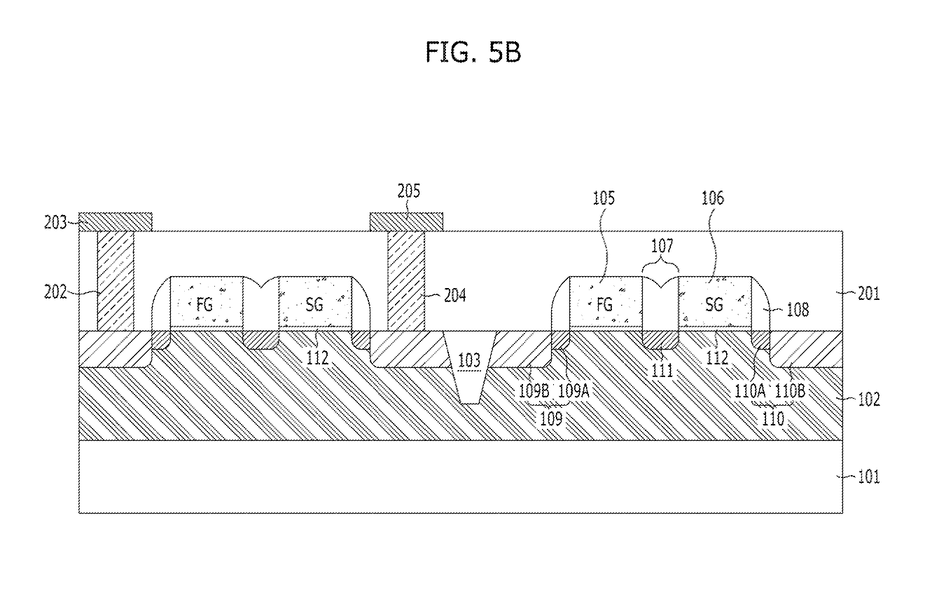

FIGS. 5A and 5B are views illustrating a cell array of the nonvolatile memory device in accordance with the embodiment of the present invention. FIG. 5A is a plan view and FIG. 5B is a cross-sectional view taken along the line A-A′ of FIG. 5A. Hereafter, for the sake of convenience in explanation, the same reference numerals as those of FIGS. 1A to 1C will be used to explain each of unit cells that constitute the cell array of the nonvolatile memory device, and detailed descriptions for components with the same reference numerals will be omitted herein.

Referring to FIGS. 5A and 5B, the nonvolatile memory device in accordance with the embodiment of the present invention may include a plurality of active regions 104, a plurality of gate lines GL that cross the plurality of active regions 104, junction regions 109 and 110 that are formed in the active regions 104 between the gate lines GL, and a first conductive line 203 and a second conductive line 205 that are respectively connected to the junction regions 109 and 110 when viewed from each gate line GL. Each gate line GL may include a plurality of floating gates 105, a select gate 106 that is adjacent to the plurality of floating gates 105 with a gap 107 defined therebetween, and spacers 108 that are formed on the sidewalls of the plurality of floating gates 105 and the select gate 106 and fill the gap 107.

The plurality of active regions 104 are defined by an isolation layer 103 that is formed in a substrate 101, and a well 102 is formed in each of the active regions 104. The active regions 104 may be line types that extend in a first direction, and may be disposed to be separated from each other by a predetermined distance in a second direction. The active regions 104 may include projections 104A that project in the second direction, for contacts between the first conductive line 203 and the junction region 109 and between the first conductive line 205 and the junction region 110. The projections 104A may be formed in a zigzag pattern in the first direction. The junction regions 109 and 110 that are formed in the active regions 104 between the gate lines GL may have structures that extend to the projections 104A.

The gate lines GL may be line types that extend in the second direction, and may be disposed to be separated from each other by a predetermined distance in the first direction. Each gate line GL includes a plurality of floating gates 105 and one select gate 106. The select gate 106 may have a sidewall that faces a sidewall of at least one floating gate 105. Floating gates 105 are disposed on portions of active regions 104 across which the gate lines GL extend.

The select gate 106 may have a shape that extends across a plurality of active regions 104 in the second direction. Each of the plurality of gate lines GL may have a shape in which floating gates 105 are disposed on one side of each gate line GL and the select gate 106 is disposed on the other side of each gate line GL. During operations, a voltage is applied to the select gate 106 of the gate line GL, and the plurality of floating gates 105 in the gate line GL may be coupled in response to the voltage applied to the select gate 106.

An interlayer dielectric layer 201 is formed on the entire surface of the substrate 101 to cover the gate lines GL. The interlayer dielectric layer 201 may include a first contact plug 202 that is connected to one junction region 109 and a second contact plug 204 that is connected to the other junction region 110 when viewed on each gate line GL. The first contact plug 202 and the second contact plug 204 may have shapes that contact the projections 104A of the active regions 104 through the interlayer dielectric layer 201. First conductive lines 203 and second conductive lines 205 are formed on the interlayer dielectric layer 201 to extend in the first direction and be respectively connected to first contact plugs 202 and second contact plugs 204. The first conductive lines 203 and the second conductive lines 205 may have shapes that are alternately disposed in the second direction while being separated from each other by a predetermined distance. The first conductive lines 203 and the second conductive lines 205 may be metal lines and may be positioned on the same plane.

Hereafter, a program operation, an erase operation and a read operation will be described with reference to Table 2 that shows cell array operating conditions of the nonvolatile memory device in accordance with the embodiment of the present invention. The operating conditions shown in Table 2 exemplify the case where the unit cell has an N channel.

TABLE 2

| | | | Program | Erase | Read |
|---|---|---|---|---|---|
| Type | | | HCI | BTBT | — |
| Selected cell [C1] | | Gate line | VPP | −VPP | VCC |
| | | First conductive line | VPP | VPP | GND/~1 V |
| | | Second conductive line | GND | GND | ~1 V/GND |
| | | Substrate (or well) | GND | GND | GND |
| Unselected | Same gate | Gate line | VPP | −VPP | VCC |
| Cell | line [C2] | First conductive line | GND | GND | GND |
| | | Second conductive line | GND | GND | GND |
| | | Substrate (or well) | GND | GND | GND |
| | Same first | Gate line | GND | GND | GND |
| | conductive line/ | First conductive line | VPP | VPP | GND/~1 V |
| | second conductive | Second conductive line | GND | GND | ~1 V/GND |
| | line [C3] | Substrate (or well) | GND | GND | GND |

First, a program operation may use HCI. In detail, as a first operation voltage, a program voltage and a ground voltage GND are respectively applied to the gate line GL of a selected cell C1, the first conductive line 203 and the second conductive line 205, charges (for example, electrons) are injected into the floating gate 105 of the selected cell C1, and thus, program may be performed in such a way as to increase the threshold voltage of the floating gate 105. The first operation voltage is applied to the select gate 106 of the gate line GL, and the first operation voltage and the program voltage may be positive voltages. For instance, the first operation voltage and the program voltage may be a pumping voltage VPP.

An unselected cell C2 that shares the gate line GL of the selected cell C1 is not programmed because the ground voltage GND is applied to the first conductive line 203 and the second conductive line 205. An unselected cell C3 that shares the first conductive line 203 or the second conductive line 205 is not programmed regardless of voltages applied to the first conductive line 203 and the second conductive line 205 because the ground voltage GND is applied to the gate line GL and the floating gate 105 is not coupled.

Next, an erase operation may use BTBT. In detail, as a second operation voltage, an erase voltage and a ground voltage GND are respectively applied to the gate line GL of the selected cell C1, the first conductive line 203 and the second conductive line 205, charges (for example, holes) are injected into the floating gate 105 of the selected cell C1, and thus, erase may be performed in such a way as to decrease the threshold voltage of the floating gate 105. The second operation voltage may be a negative voltage, and the erase voltage may be a positive voltage. For instance, the second operation voltage may be a negative pumping voltage −VPP and the erase voltage may be a pumping voltage VPP.

The unselected cell C2 that shares the gate line GL of the selected cell C1 is not erased because the ground voltage GND is applied to the first conductive line 203 and the second conductive line 205. The unselected cell C3 that shares the first conductive line 203 or the second conductive line 205 is not erased regardless of voltages applied to the first conductive line 203 and the second conductive line 205 because the ground voltage GND is applied to the gate line GL and the floating gate 105 is not coupled.

In succession, both forward read and reverse read may be possible in a read operation. In the forward read, the selected cell C1 may be read by applying a third operation voltage, a read voltage and a ground voltage GND to the gate line GL of the selected cell C1, the first conductive line 203 and the second conductive line 205, respectively. Further, in the reverse read, the selected cell C1 may be read by applying a third operation voltage, a ground voltage GND and a read voltage to the gate line GL of the selected cell C1, the first conductive line 203 and the second conductive line 205, respectively. The third operation voltage and the read voltage may be positive voltages. The read voltage may be smaller than the third operation voltage, and the third operation voltage may be smaller than the first operation voltage. For instance, the third operation voltage may be a power supply voltage VCC and the read voltage may be 1V.

The unselected cell C2 that shares the gate line GL of the selected cell C1 may not be read because the ground voltage GND is applied to the first conductive line 203 and the second conductive line 205. The unselected cell C3 that shares the first conductive line 203 or the second conductive line 205 may not be read regardless of voltages applied to the first conductive line 203 and the second conductive line 205 because the ground voltage GND is applied to the gate line GL and the floating gate 105 is not coupled.

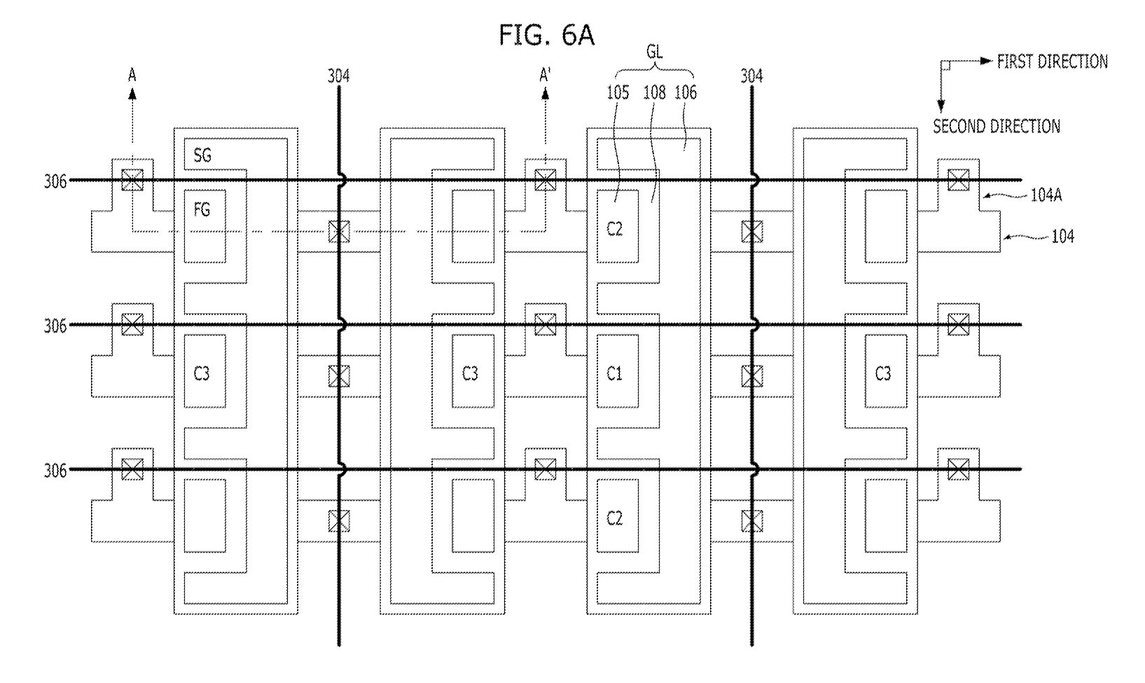

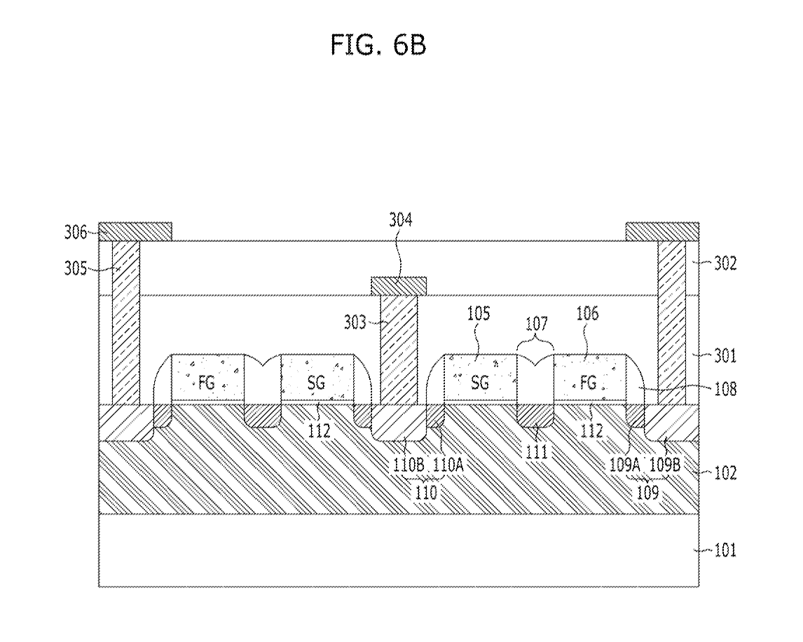

FIGS. 6A and 6B are views illustrating a cell array of a nonvolatile memory device in accordance with another embodiment of the present invention. FIG. 6A is a plan view and FIG. 6B is a cross-sectional view taken along the line A-A′ of FIG. 6A. Hereafter, for the sake of convenience in explanation, the same reference numerals as those of FIGS. 1A to 1C will be used to explain each of unit cells that constitute the cell array of the nonvolatile memory device, and detailed descriptions for components with the same reference numerals will be omitted herein.

Referring to FIGS. 6A and 6B, a nonvolatile memory device in accordance with another embodiment of the present invention may include a plurality of active regions 104, a plurality of gate lines GL that cross the plurality of active regions 104, junction regions 109 and 110 that are formed in the active regions 104 between the gate lines GL, and a first conductive line 306 and a second conductive line 304 that are respectively connected to the junction regions 109 and 110 when viewed from each gate line GL. Each gate line GL may include a plurality of floating gates 105, a select gate 106 that is adjacent to the plurality of floating gates 105 with a gap 107 defined therebetween, and spacers 108 that are formed on the sidewalls of the plurality of floating gates 105 and the select gate 106 and fill the gap 107.

The plurality of active regions 104 are defined by an isolation layer 103 that is formed in a substrate 101, and a well 102 is formed in each of the active regions 104. The active regions 104 may be line types that extend in a first direction, and may be disposed to be separated from each other by a predetermined distance in a second direction. The active regions 104 may include projections 104A that project in the second direction, for contacts between the first conductive line 306 and the junction region 109 and between the second conductive line 304 and the junction region 110, respectively. The junction regions 109 that are formed in the active regions 104 between the gate lines GL may have structures that extend to the projections 104A.

The gate lines GL may be line types that extend in the second direction, and may be disposed to be separated from each other by a predetermined distance in the first direction. Each gate line GL includes a plurality of floating gates 105 and one select gate 106. The select gate 106 may have a sidewall that faces a sidewall of at least one floating gate 105. Floating gates 105 are disposed on portions of active regions 104 across which the gate lines GL extend, and the select gate 106 may have a shape that extends across a plurality of active regions 104 in the second direction. Each of the gate lines GL may have such a shape that the select gate 106 and the floating gate 105 of a gate line GL respectively face the select gate 106 of another gate line GL adjacent to one side of the gate line GL and the floating gate 105 of still another gate line GL adjacent to the other side of the gate line GL. During operations, a voltage is applied to the select gate 106 of the gate line GL, and the plurality of floating gates 105 in the gate line GL may be coupled in response to the voltage applied to the select gate 106.

A first interlayer dielectric layer 301 is formed on the entire surface of the substrate 101 to cover the gate lines GL, and a second interlayer dielectric layer 302 is formed on the first interlayer dielectric layer 301. A plurality of first conductive lines 306 are formed on the second interlayer dielectric layer 302 to extend in the first direction, and a plurality of second conductive lines 304 are formed on the first interlayer dielectric layer 301 to extend in the second direction. The junction regions 109 adjacent to the floating gates 105 of the gate lines GL are connected to the first conductive lines 306 through first contact plugs 305 that pass through the first interlayer dielectric layer 301 and the second interlayer dielectric layer 302. The junction regions 110 adjacent to the select gates 106 of the gate lines GL are connected to the second conductive lines 304 through second contact plugs 303 that pass through the first interlayer dielectric layer 301. The first conductive lines 306 and the second conductive lines 304 may be metal lines.

Hereafter, a program operation, an erase operation and a read operation will be described with reference to Table 3 that shows cell array operating conditions of the nonvolatile memory device in accordance with another embodiment of the present invention. The operating conditions shown in Table 3 exemplify the case where the unit cell has an N channel.

TABLE 3

| | | | Program | Erase | Read |
|---|---|---|---|---|---|
| Type | | | HCI | BTBT | — |
| Selected cell [C1] | | Gate line | VPP | −VPP | VCC |
| | | First conductive line | VPP | VPP | ~1 V |
| | | Second conductive line | GND | GND | GND |
| | | Substrate (or well) | GND | GND | GND |
| Un- | Same gate | Gate line | VPP | −VPP | VCC |
| selected | line [C2] | First conductive line | GND | GND | GND |
| Cell | | Second conductive line | GND | GND | GND |
| | | Substrate (or well) | GND | GND | GND |
| | Same first | Gate line | GND | GND | GND |
| | conductive | First conductive line | VPP | VPP | ~1 V |
| | line | Second conductive line | GND | GND | GND |
| | [C3] | Substrate (or well) | GND | GND | GND |

First, a program operation may use HCI. In detail, as a first operation voltage, a program voltage and a ground voltage GND are respectively applied to the gate line GL of a selected cell C1, the first conductive line 306 and the second conductive line 304, charges (for example, electrons) are injected into the floating gate 105 of the selected cell C1, and thus, program may be performed in such a way as to increase the threshold voltage of the floating gate 105. The first operation voltage is applied to the select gate 106 of the gate line GL, and the first operation voltage and the program voltage may be positive voltages. For instance, the first operation voltage and the program voltage may be a pumping voltage VPP.

An unselected cell C2 that shares the gate line GL of the selected cell C1 is not programmed because the ground voltage GND is applied to the first conductive line 306 and the second conductive line 304. An unselected cell C3 that shares the first conductive line 306 is not programmed regardless of a voltage applied to the first conductive line 306 because the ground voltage GND is applied to the gate line GL and the floating gate 105 is not coupled.

Next, an erase operation may use BTBT. In detail, as a second operation voltage, an erase voltage and the ground voltage GND are respectively applied to the gate line GL of the selected cell C1, the first conductive line 306 and the second conductive line 304, charges (for example, holes) are injected into the floating gate 105 of the selected cell C1, and thus, erase may be performed in such a way as to decrease the threshold voltage of the floating gate 105. The second operation voltage may be a negative voltage, and the erase voltage may be a positive voltage. For instance, the second operation voltage may be a negative pumping voltage −VPP and the erase voltage may be the pumping voltage VPP.

The unselected cell C2 that shares the gate line GL of the selected cell C1 is not erased because the ground voltage GND is applied to the first conductive line 306 and the second conductive line 304. The unselected cell C3 that shares the first conductive line 306 is not erased regardless of a voltage applied to the first conductive line 306 because the ground voltage GND is applied to the gate line GL and the floating gate 105 is not coupled.

In succession, in a read operation, since the second conductive line 304 that is connected to the junction region 110 between the select gates 106 of two adjacent gate lines GL serves as a common line, forward read may be used. In detail, the selected cell C1 may be read by applying a third operation voltage, a read voltage and a ground voltage GND to the gate line GL of the selected cell C1, the first conductive line 306 and the second conductive line 304, respectively. The third operation voltage and the read voltage may be positive voltages. The read voltage may be smaller than the third operation voltage, and the third operation voltage may be smaller than the first operation voltage. For instance, the third operation voltage may be a power supply voltage VCC and the read voltage may be 1V.

The unselected cell C2 that shares the gate line GL of the selected cell C1 may not be read because the ground voltage GND is applied to the first conductive line 306 and the second conductive line 304. The unselected cell C3 that shares the first conductive line 306 may not be read regardless of a voltage applied to the first conductive line 306 because the ground voltage GND is applied to the gate line GL and the floating gate 105 is not coupled.

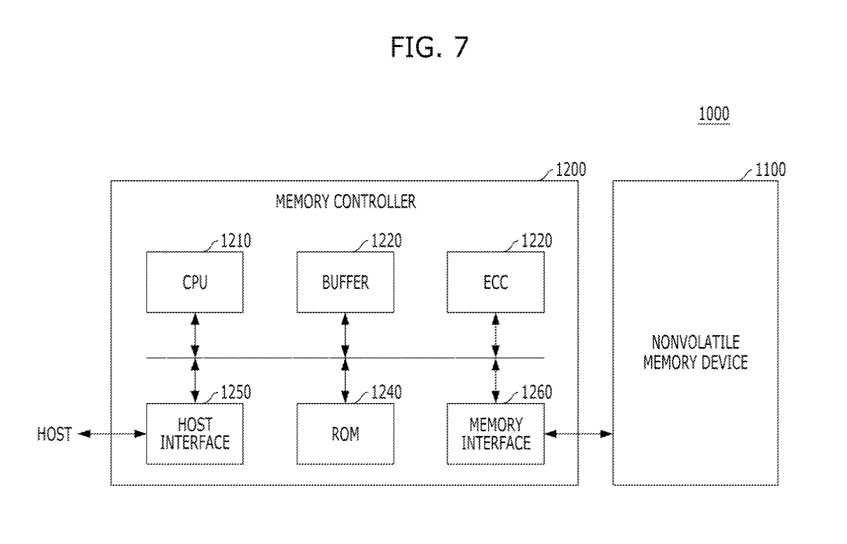

FIG. 7 is a block diagram showing a memory system including the nonvolatile memory device in accordance with the embodiments of the present invention.

Referring to FIG. 7, a memory system 1000 may include a nonvolatile memory device 1100, and a memory controller 1200 configured to control general data exchange between a host HOST and the nonvolatile memory device 1100. The nonvolatile memory device 1100 is realized by including the unit cell, the operating method and the cell array of the nonvolatile memory device in accordance with the embodiment of the present invention. The memory controller 1200 may include a CPU 1210, a buffer 1220, an ECC circuit 1230, a ROM 1240, a host interface 1250, and a memory interface 1260.

The memory system 1000 may be provided in the form of a personal digital assistant (PDA), a portable computer, a web tablet, a wireless phone, a mobile phone, a digital music player, a memory card, all electronic products that may transmit and/or receive information in a wireless environment, a solid state disk, a camera image sensor, and an application chipset.

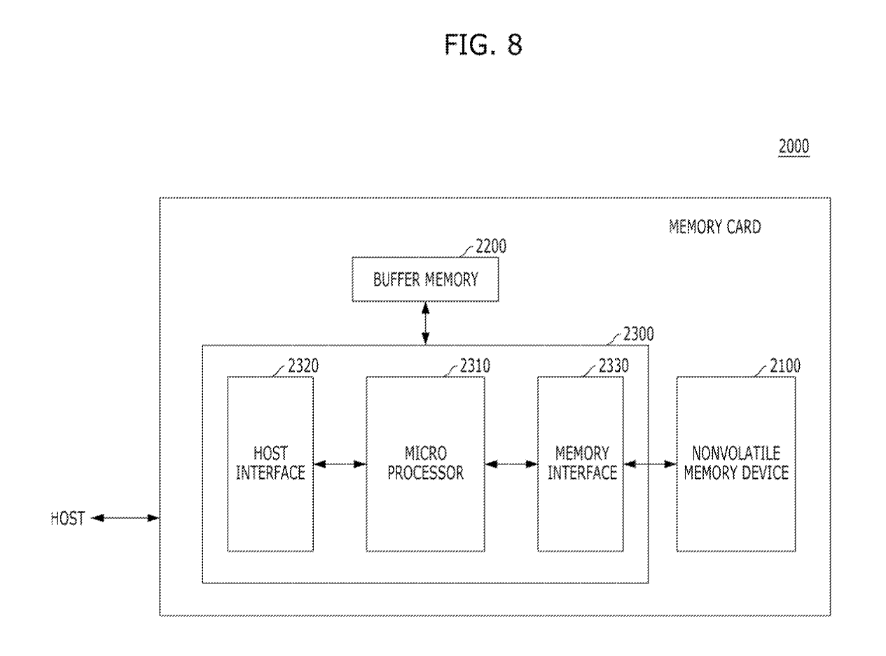

FIG. 8 is a block diagram showing a memory card including the nonvolatile memory device in accordance with the embodiments of the present invention.

Referring to FIG. 8, a memory card 2000 includes a nonvolatile memory device 2100, a buffer memory device 2200, and a memory controller 2300 that controls the nonvolatile memory device 2100 and the buffer memory device 2200. The nonvolatile memory device 2100 is realized by including the unit cell, the operating method and the cell array of the nonvolatile memory device in accordance with the embodiment of the present invention. The buffer memory device 2200 is a device for temporarily storing data that is generated during the operation of the memory card 2000. The buffer memory device 2200 may be realized by a DRAM or an SRAM. The memory controller 2300 is connected between a host HOST and the nonvolatile memory device 2100. The memory controller 2300 accesses the nonvolatile memory device 2100 in response to a request from the host HOST. The memory controller 2300 includes a micro processor 2310, a host interface 2320, and a memory interface 2330. The micro processor 2310 is realized to operate firmware. The host interface 2320 interfaces with the host HOST through a card (for example, MMC) protocol for performing data exchange between the host HOST and the memory interface 2330.

The memory card 2000 may be applicable to a multimedia card (MMC), a security digital (SD) card, a miniSD card, a memory stick, a SmartMedia card, a TransFlash card, etc.

The nonvolatile memory device in accordance with the embodiment of the present invention and an application device including the same may be mounted as various types of packages. For example, the nonvolatile memory device and the application device including the same may be packaged and mounted in the form of a package on package (PoP), ball grid arrays (BGAs), chip scale packages (CSPs), a plastic leaded chip carrier (PLCC), a plastic dual in-line package (PDIP), a die in waffle pack, a die in wafer form, a chip on board (COB), a ceramic dual in-line package (CERDIP), a plastic metric quad flat package (MQFP), a small outline (SOIC), a shrink small outline package (SSOP), a thin small outline package (TSOP), a thin quad flat package (TQFP), a system in package (SIP), a multi-chip package (MCP), a wafer-level fabricated package (WFP), a wafer-level processed stack package (WSP), and wafer-level chip scale packages (WLCSPs).

As is apparent from the above descriptions, in the embodiments of the present invention, since a unit cell has a floating gate, a select gate that is adjacent to the floating gate with a gap defined therebetween and a spacer that fills the gap, a nonvolatile memory device may be fabricated in conformity with a logic process without a separate additional process, and high degree of integration may be realized.

Also, in the embodiments of the present invention, since the spacer that fills the gap serves as a dielectric layer between the floating gate and the select gate, a fabrication process may be simplified and the degree of integration may be increased, and as the degree of integration increases, a coupling ratio between the floating gate and the select gate may be increased.

Further, in the embodiments of the present invention, since the select gate that performs the function of a control gate for coupling the floating gate is provided, over-erase may be prevented, and the operation characteristics of a nonvolatile memory device may be improved.

Although various embodiments have been described for illustrative purposes, it will be apparent to those skilled in the art that various changes and modifications may be made without departing from the spirit and scope of the invention as defined in the following claims.

What is claimed is:

1. A nonvolatile memory device comprising:
a floating gate formed over a substrate;
a select gate formed adjacent to the floating gate with a gap defined therebetween;
spacers formed on sidewalls of the floating gate and the select gate and filling the gap;
a first junction region formed in a portion of the substrate adjacent to the floating gate; and
a second junction region formed in a portion of the substrate adjacent to the select gate.

2. The nonvolatile memory device according to claim 1, further comprising:
a third junction region formed in a portion of the substrate under the gap.

3. The nonvolatile memory device according to claim 2,
wherein the first junction region and the second junction region comprise first impurity regions and second impurity regions that have larger impurity doping concentrations than those of the first impurity regions, respectively, and
wherein the third junction region comprises an impurity region the same as the first impurity regions.

4. The nonvolatile memory device according to claim 1, wherein the select gate has a sidewall that faces a sidewall of the floating gate.

5. The nonvolatile memory device according to claim 1, wherein an upper surface of the floating gate and an upper surface of the select gate are positioned on a same plane.

6. The nonvolatile memory device according to claim 1,
wherein the floating gate and the select gate comprise a polyslicon layer, and
wherein the spacers comprise a dielectric layer.

7. The nonvolatile memory device according to claim 1, wherein the floating gate is coupled to the select gate in response to a voltage applied to the select gate.

8. The nonvolatile memory device according to claim 1, wherein a coupling ratio between the select gate and the floating gate increases as a width of the gap decreases.

9. A nonvolatile memory device comprising:
a plurality of active regions;
a plurality of gate lines crossing the plurality of active regions;
junction regions formed in the active regions between the gate lines; and
a first conductive line and a second conductive line respectively connected to one and the other junction regions when viewed on each of the plurality of gate lines,
wherein each of the plurality of gate lines comprises a plurality of floating gates, a select gate that is adjacent to the plurality of floating gates with gaps defined therebetween, and spacers that are formed on sidewalls of the floating gates and the select gate and fill the gaps.

10. The nonvolatile memory device according to claim 9, wherein the plurality of floating gates are positioned over the plurality of active regions, and the select gate extends across the plurality of active regions.

11. The nonvolatile memory device according to claim 9, wherein any one gate line and an adjacent gate line have shapes in which their floating gates or select gates face each other, or shapes in which the floating gates of the any one gate line and the select gate of the adjacent gate line face each other.

12. The nonvolatile memory device according to claim 9, wherein a plurality of floating gates of any one gate line are coupled to the select gate in response to a voltage applied to a select gate of the any one gate line.

13. The nonvolatile memory device according to claim 9, wherein coupling ratios between the select gate and the plurality of floating gates increase as a width of the gap decreases.
